(19) United States
(12) Patent Application Publication
(10) Pub. No.: US 2023/0298978 A1
(43) Pub. Date: Sep. 21, 2023

(54) Package, Lead Frame and Roughening Method Thereof

(71) Applicant: Diodes Incorporated, Plano, TX (US)

(72) Inventors: Xiaorui Yang, Shanghai (CN); Jian Jin, Shanghai (CN)

(21) Appl. No.: 18/202,272

(22) Filed: May 25, 2023

Related U.S. Application Data
(63) Continuation of application No. PCT/CN2022/102749, filed on Jun. 30, 2022.

(30) Foreign Application Priority Data
Aug. 26, 2021 (CN) 202110989022.5
Aug. 26, 2021 (CN) 202122035934.7

(51) Int. Cl. H01L 23/495; H01L 23/00; H01L 23/31; H01L 21/48; H01L 21/56

(52) U.S. Cl. CPC H01L 23/49565; H01L 24/48; H01L 24/32; H01L 24/73; H01L 23/3107; H01L 21/4842; H01L 21/56; H01L 2224/48245; H01L 2224/32245; H01L 2224/73265

(57) ABSTRACT

A lead frame includes a plurality of lead frame units. An upper surface of each of the plurality of lead frame units includes a soldering region and a non-soldering region outside of the soldering region. The non-soldering region includes a rough surface, and the soldering surface includes no rough surface. Each of the plurality of lead frame units may include a base island and a plurality of pins arranged around the base island, and the soldering region may be arranged on the base island and/or on the plurality of pins. The soldering region my include a wire-bonding soldering portion that connects to a chip via a bonding wire. Each of the plurality of lead frame units may include a plurality of pins, and the soldering region and the non-soldering region are arranged on the plurality of pins.

### CROSS-REFERENCE TO RELATED APPLICATIONS

This patent application is continuation of International Application No. PCT/CN2022/102749, filed on Jun. 30, 2022, which claims priority to Chinese Application No. 202110989022.5, filed on Aug. 26, 2021 and entitled “Package, lead frame and roughening method thereof,” and Chinese Application No. 202122035934.7, filed on Aug. 26, 2021 and entitled “Package and lead frame.” The aforementioned applications are hereby incorporated by reference herein as if reproduced in their entireties.

### TECHNICAL FIELD

The present disclosure relates to the field of semiconductor packaging, and in particular embodiments, to a package, lead frame and roughening method thereof.

### BACKGROUND

In order to improve the bonding strength between a plastic packaging material and the surface of a lead frame, so that the plastic packaging material and surface of the lead frame have stronger bond, in some cases, the surface of the lead frame may need to be roughened before packaging is performed.

In the existing technologies, the surface of the lead frame is generally roughened by micro-etching or oxidation. Specifically, chemicals are usually used to treat the copper surface of the lead frame to form a rough surface. However, the rough surface produced by this roughening process is the copper surface of the entire lead frame, that is, the roughening process is generally used to roughen the entire surface of the lead frame. Further, the roughening depth of the surface roughened by chemicals is relatively shallow and the depth is not fully controllable.

Furthermore, since the lead frame of wire-bonding products has a gold and/or silver plating layer, the roughened surface may be covered by the plating layer, and thus the fully roughened lead frame has not much effect on packaging of the wire-bonding products. Flux may spread on the gold and/or silver plating, and so flip-chip products usually use a bare copper frame as the lead frame. However, the roughened copper surface is not conducive to the wetting of the flux to the solder balls, and the roughened copper surface is not well bonded to the melted solder, which is prone to voids. Thus, a lead frame with its entire surface roughened, although can enhance the bonding strength between the plastic packaging material of a flip-chip product and the surface of the lead frame, is not friendly to soldering tin, and so the lead frame with the entire surface roughened has a great impact on the soldering effect of the flip-chip product.

Therefore, it is desirable to provide a package, a lead frame and a roughening method thereof to resolve the above-mentioned problems.

It should be noted that the above description about the technical background is only for the convenience of providing a clear and complete description of the technical solutions of the present application, and for the convenience of understanding by those of ordinarily skilled in the art. It should not be considered that the above-mentioned technical solutions have been known to those of ordinarily skilled in the art just because these solutions are explained in the background of the present application.

### SUMMARY

Technical advantages are generally achieved, by embodiments of this disclosure which describe a package, lead frame and roughening method thereof.

In view of the description above, a technical problem to be solved by the present application is to provide a package, a lead frame and a roughening method thereof, which, on one hand, can enhance the bonding strength between a plastic packaging material and the surface of the lead frame, and on the other hand, can improve the soldering effect, avoid problems that are caused by the rough surface, such as wire-bonding flying, and insecure soldering, and avoid problems such as voids and pseudo soldering during flip-chip soldering.

In order to achieve the above objectives, embodiments of the present application provide a lead frame, comprising: a plurality of lead frame units, wherein the upper surface of each of the plurality of lead frame units is divided into a soldering region and a non-soldering region located outside the soldering region, the non-soldering region is provided with a rough surface, and the soldering region does not have a rough surface.

As a preferred optional embodiment, a lead frame unit includes a base island and a plurality of pins arranged around the base island, and the soldering region is arranged on the base island and/or on the plurality of pins.

As a preferred optional embodiment, the soldering region includes at least one wire-bonding soldering portion, and the at least one wire-bonding soldering portion is electrically connected to a chip via a bonding wire.

As a preferred optional embodiment, a lead frame unit includes a plurality of pins, and the soldering region and the non-soldering region are arranged on each of the plurality of pins, and the non-soldering region and the soldering region on a pin are arranged, respectively, close to and away from a cutting line of the lead frame.

As a preferred optional embodiment, at least one soldering pad is provided in the soldering region, and a chip is flip-chip soldered on the at least one soldering pad.

As a preferred optional embodiment, the lead frame further includes an outer frame, the outer frame is arranged around the plurality of lead frame units, each of the plurality of lead frame units further includes a plurality of connecting ribs, the plurality of connecting ribs correspond to the plurality of pins, and each of the plurality of connecting ribs is configured to connect the outer frame with a corresponding pin of the plurality of pins.

As a preferred optional embodiment, the rough surface is formed using ablation slots, and the ablation slots are generated using laser high-speed pulses.

As a preferred optional embodiment, the laser high-speed pulses are emitted by a laser emitter that has power from 290 watts to 300 watts, and a wavelength of the laser high-speed pulses is from 530 nanometer (nm) to 535 nm.

As a preferred optional embodiment, a depth of the ablation slots is in a range from 0.035 mm (millimeter) to 0.05 mm.

A package including a lead frame as described above; and a plastic package for packaging the lead frame, wherein the plastic package and the rough surface form a locking structure.

A roughening method for a lead frame, the lead frame comprising a plurality of lead frame units. The roughening method includes: ablating, using a laser emitter, a portion of an upper surface of each of the plurality of lead frame units to form ablation slots in the portion of the upper surface, such that the upper surface is divided into a soldering region excluding the ablation slots and a non-soldering region including the ablation slots.

As a preferred optional embodiment, the laser emitter has power from 290 watts to 300 watts, and the laser emitter is used to emit laser high-speed pulses having a wavelength from 530 nanometer (nm) to 535 nm.

According to one aspect of the present application, a lead frame is provided that includes a plurality of lead frame units. An upper surface of each of the plurality of lead frame units includes a soldering region and a non-soldering region outside of the soldering region, the non-soldering region includes a rough surface, and the soldering surface includes no rough surface.

According to another aspect of the present application, a package is provided that includes a lead frame comprising a plurality of lead frame units. An upper surface of each of the plurality of lead frame units includes a soldering region and a non-soldering region outside of the soldering region, the non-soldering region includes a rough surface, and the soldering surface includes no rough surface. The package also includes a plastic package for packaging the lead frame, wherein the plastic package and the rough surface form a locking structure.

According to another aspect of the present application, a method is provided including: providing a lead frame, the lead frame comprising a plurality of lead frame units; and ablating, using a laser emitter, a portion of an upper surface of each of the plurality of lead frame units to form ablation slots in the portion of the upper surface, to generate, on the upper surface, a non-soldering region comprising the ablation slots and a soldering region excluding the ablation slots.

The technical effect of the present application is that, a package, a lead frame and a roughening method thereof are provided. The lead frame is provided with lead frame units, and a lead frame unit is provided with a soldering region and a non-soldering region. The non-soldering region has a rough surface, and the soldering region has no rough surface. When packaging, the non-soldered region is bonded to the plastic packaging material. Thus, the bonding strength between the plastic packaging material and the surface of the lead frame is enhanced through the rough surface, and the plastic packaging material and the surface of the lead frame are bonded more securely. Since the soldering region does not have the rough surface, the copper surface of the soldering region can be well bonded with the melted solder, which can avoid issues such as voids and pseudo soldering during flip-chip soldering, and is conducive to wetting the solder balls with flux, producing good soldering results. Further, the soldering region can avoid problems caused by the rough surface, such as wire-bonding flying and insecure soldering, and so on. That is, in the lead frame according to embodiments of the present invention, by dividing the surface of a lead frame unit into the soldering region and the non-soldering region, and only roughening the non-soldering region, the surface of the lead frame unit is partially roughened, not fully roughened as in the prior art. In this way, on one hand, the bonding strength between the plastic packaging material and the surface of the lead frame is enhanced, and on the other hand, the soldering effect is improved and the voids are avoided. As such, embodiments of the application provide a package, a lead frame and a roughening method thereof, which, on one hand, can enhance the bonding strength of the plastic packaging material and the lead frame surface, and on the other hand, can improve soldering effect, avoid problems including wire-bonding flying, insecure soldering, and so on, that are caused by rough surface, and avoid problems including voids and pseudo soldering, and so on, in flip-chip soldering.

### BRIEF DESCRIPTION OF THE DRAWINGS

The technical solutions and beneficial effects of the present application will be made apparent through the detailed description of embodiments of the present application in conjunction with the accompanying drawings, in which:

FIG. 1 is a diagram of an example top view of a lead frame according to an embodiment of the present application;

FIG. 2 is a diagram of an example top view of a lead frame unit according to a first embodiment of the present application;

FIG. 3 is a diagram of a top view of an example lead frame unit according to a second embodiment of the present application;

FIG. 4 is a diagram of a state of an example lead frame body according to an embodiment of the present application;

FIG. 5 is a diagram of a state of an example lead frame body after ablation according to an embodiment of the present application; and

FIG. 6 is schematic structural diagram of example ablation slots according to an embodiment of the present application.

Explanation of reference signs in the drawings: 11, lead frame unit; 13, outer frame; 15, connecting rib; 16, pin; 17, pad; 18, non-soldering region; 19, soldering region; 21, base island; 25, bonding wire; 26, chip; 27, rough surface; 28, ablation slots.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of embodiments of this disclosure are discussed in detail below. It should be appreciated, however, that the concepts disclosed herein can be embodied in a wide variety of specific contexts, and that the specific embodiments discussed herein are merely illustrative and do not serve to limit the scope of the claims. Further, it should be understood that various changes, substitutions and alterations can be made herein without departing from the spirit and scope of this disclosure as defined by the appended claims.

The following provides clear and complete description of the technical solutions in embodiments of the present application with reference to the accompanying drawings in embodiments of the present application. It is apparent that the described embodiments are only some, but not all, embodiments of the present application. Based on the embodiments of the present application, all other embodiments obtained by persons of ordinary skill in the art without taking creative efforts belong to the protection scope of this application.

In the description of the present application, it should be understood that the terms “central”, “longitudinal”, “transverse”, “length”, “width”, “thickness”, “up”, “down”, “front”, “back”, “left”, “right”, “vertical”, “horizontal”, “top”, “bottom”, “inner”, “outer”, “clockwise”, “counterclockwise”, and so on, indicate orientation or position relationships based on orientation or position relationships as shown in the accompanying drawings, and are only used to facilitate the description of the present application and simplify the description. They do not indicate or imply that a device or element referred to must have a specific orientation, or must be constructed and operated in a specific orientation, and therefore cannot be construed as limiting the present application. In addition, the terms “first”, and “second” are used for descriptive purposes only, and should not be understood as indicating or implying relative importance or as implying the number of technical features indicated. Thus, a feature limited by “first” or “second” may explicitly or implicitly include one or more of the feature. In the description of the present application, “multiple” means two or more, unless otherwise clearly and specifically defined.

In the description of the present application, it should be noted that, unless otherwise specified and limited, the terms “installation”, “connected” and “connection” should be understood in a broad sense. For example, “connection” can be fixed connection, detachable connection, or integral connection; it can be mechanical connection, electrical connection or it means being communicable with each other; it can be directly connected or indirectly connected through an intermediate medium, and it can be the internal connection of two components or an interaction relationship between two components. For those of ordinary skill in the art, the specific meanings of the above terms in the present application can be understood according to specific situations.

In the present application, unless otherwise clearly stated and limited, a first feature being “above” or “under” a second feature may include that the first feature and the second feature are in direct contact, and may also include that the first feature and the second feature are not in direct contact but are in contact through another feature therebetween. Moreover, a first feature being “on”, “above” and “over” a second feature includes that the first feature is directly above and obliquely above the second feature, or simply means that the first feature's level height is greater than that of the second feature. A first feature being “under”, “below” or “beneath” a second feature may include that the first feature is directly below and obliquely below the second feature, or simply mean that the first feature's level height is less than that of the second feature.

The following provides different embodiments or examples for implementing different structures of the present application. To simplify the description of the present application, components and arrangements of specific examples are described below. Certainly, they are merely examples for illustration, and are not intended to limit the application. Furthermore, in the description of the present disclosure, reference numerals and/or reference letters may be repetitively referred to in different embodiments, and such repetition is for simplicity and clarity, and does not in itself indicate a relationship between the different embodiments and/or arrangements discussed. In addition, various specific example processes and materials are provided in the present application, but one of ordinary skill in the art may recognize the application of other processes and/or the use of other materials.

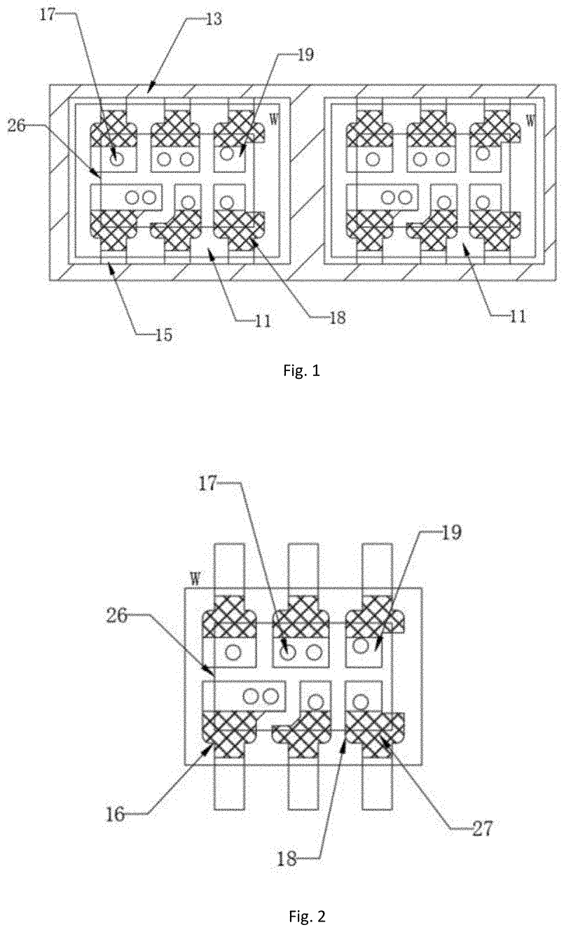

Specifically, as shown in the FIG. 1, one embodiment of the present application provides a lead frame. The lead frame includes: a plurality of lead frame units 11, where the upper surface of each of the plurality of lead frame units 11 is divided into soldering regions 19, and non-soldering regions 18 located outside of the soldering regions 19. The non-soldering regions 19 have rough surfaces 27, the soldering regions 19 do not have the rough surfaces 27.

It can be seen from the above technical solutions: the lead frame according to the embodiment of the present application is provided with the lead frame units 11. Each lead frame unit 11 is provided with the soldering regions 19 and the non-soldering regions 18. The non-soldering regions 19 are configured to have the rough surfaces 27 (FIG. 2), and the soldering regions 19 do not have the rough surfaces 27. In packaging, the non-soldered regions 18 are bonded to the plastic packaging material. Thus, the bonding strength between the plastic packaging material and the surface of the lead frame is enhanced through the rough surfaces 27, and the plastic packaging material and the surface of the frame are bonded more securely. Since the soldering regions 19 do not have the rough surfaces 27, the copper surface of the soldering regions 19 can be well bonded with the melted solder, which can avoid issues such as voids and pseudo soldering during flip-chip soldering, and is conducive to wetting the solder balls with flux, producing good soldering results. Further, the soldering regions 19 can avoid problems caused by rough surface, such as wire-bonding flying and insecure soldering, and so on. That is, in the lead frame according to the embodiment of the present invention, by dividing the surface of the lead frame unit 11 into soldering regions 19 and non-soldering regions 18, and only roughening the non-soldering regions 18, the surface of the lead frame unit 11 is partially roughened, not fully roughened as in the prior art. In this way, on one hand, the bonding strength between the plastic packaging material and the surface of the lead frame is enhanced, and on the other hand, the soldering effect can be improved and the voids are avoided.

Further, the lead frame according to the embodiment of the present invention includes a plurality of lead frame units 11. The quantity of the plurality of lead frame units 11 may be 2, 3, 4, etc., which is not limited in the present application. For example, as shown in FIG. 1, the present application provides an example lead frame. The lead frame includes two lead frame units 11 defined by cutting lines W as border. Each lead frame unit 11, after being cut, can be used to build a package (a semiconductor device). In the following, the structure of one lead frame unit 11 is used as an example for illustration.

Further, the upper surface of each lead frame unit 11 includes the soldering regions 19 and the non-soldering regions 18 located outside of the soldering regions 19. In other words, the upper surface of each lead frame unit 11 is divided into the solder regions 19 and the non-soldering regions 18. Furthermore, the non-soldering regions 18 have the rough surfaces 27, through which, the bonding strength between the plastic packaging material and the surface of the lead frame is enhanced, and the plastic packaging material and the surface of the frame are bonded more securely. Further, the soldering regions 19 do not have the rough surfaces 27. That is, the surfaces of the soldering regions 19 is not roughened. Thus, the unroughened copper surfaces are well bonded with the melted solder, which can avoid problems such as voids and pseudo soldering occurred in flip-chip soldering, and is conducive to wetting the solder ball by the flux, thereby producing good soldering results. Furthermore, the soldering regions 19 can avoid problems such as wire-bonding flying and poor soldering that are caused by rough surfaces.

Furthermore, the rough surfaces 27 are formed by ablation slots 28 (FIG. 6). Specifically, the ablation slots 28 may be in a mesh pattern. The ablation slots 28 are not limited to the mesh pattern, and may be in other applicable patterns, for example, the ablation slots 28 may be in a pattern of stripes, flowers, cross-over, and so on.

Further, the ablation slots 28 are formed by using laser high-speed pulses. Specifically, the laser high-speed pulses are emitted by a laser emitter having power in the range from 290 Watts to 300 Watts, and the wavelength of the laser high-speed pulses is in a range from 530 nm (nanometer) to 535 nm. By use of laser to perform region-selective roughening on the surface of the lead frame unit 11, the roughening operation is made more convenient and flexible. The use of laser to perform region-selective roughening on the surface of the lead frame unit also reduces the cost. Specifically, according to the existing technologies, in order to meet the packaging requirements of flip-chip products, to enhance the bonding strength between the plastic packaging material and the surface of the lead frame on one hand, and to improve the soldering effect and avoid the voids on the other hand, it is generally chosen to perform region-selective roughening to the lead frame. More specifically, region(s) that do not need to be roughened may be covered with a chemical mask, and region(s) that need to be roughened may be roughened with a chemical potion. Such a roughening operation requires addition of processes including film drying, exposing, developing, and so on, resulting in an increase in the cost of the lead frame, which is not conducive to the overall competitiveness of the products. The embodiment operation of region-selective roughening of surfaces of the lead frame units 11 by laser is simple, can avoid the additional multiple processes including film drying, exposing, developing, and so on, and thus the cost is lower. Moreover, the roughening of the lead frame according to the embodiment of the present application does not require the use of chemical potions, thereby avoiding causing secondary pollution to the lead frame. In addition, by controlling the laser energy, the roughening depth is controllable, such that the roughening depth can be made deeper than the conventional roughening, and the plastic packaging material can be locked more easily.

Furthermore, the fully roughening process in the prior art cannot accurately control the depth of surface roughening, and is thus unable to achieve larger roughening depth, while the roughening process by laser can precisely control the roughening depth. Specifically, as shown in FIG. 6, the depth of the ablation slots 28 can be 0.035 mm to 0.05 mm. This enables better locking of the plastic packaging material.

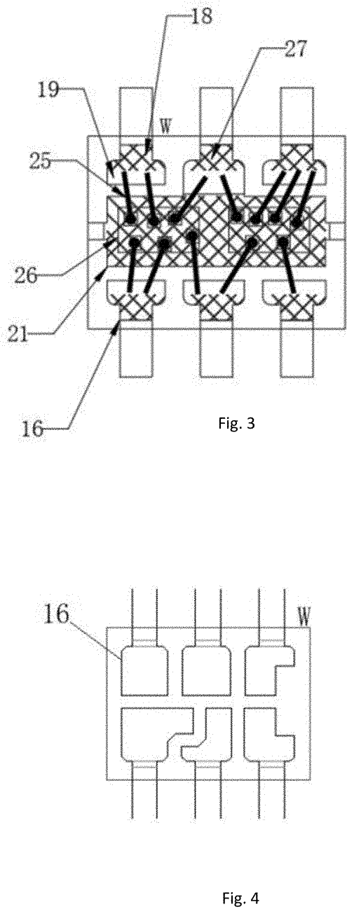

Further, FIG. 2 is a schematic diagram of an example structure of a lead frame according to a first embodiment of the present application. FIG. 3 is a schematic diagram of an example structure of a lead frame according to a second embodiment of the present application. The first embodiment and the second embodiment will be described in the following with reference to FIG. 2 and FIG. 3.

As shown in the FIG. 2, in a lead frame unit 11 of the first embodiment, the lead frame unit 11 includes multiple pins 16. The number of the multiple pins 16 may be 2, 3, 4, etc., which is not limited in this application. For example, as shown in FIG. 2, the lead frame unit 11 include 6 pins 16. Further, each pin 16 includes a soldering region 19 and a non-soldering region 18. The soldering region 19 includes at least one pad 17. The number of the at least one pad 17 may be one (1) or more. The at least one pad 17 may be used for flip-chip soldering of a chip 26, where the lead frame unit 11 is used for flip-chip packaging. Specifically, the chip 26 may be soldered flip-chip to the at least one pad 17 via solder ball(s). Certainly, the chip 26 can be flip-chip soldered to the pad 17 not only by solder ball(s), but also by gold ball(s) or tin-headed copper pillar(s), which is not limited in the application. Thus, as shown in FIG. 2, in the lead frame unit 11 of the first embodiment, each pin 16 is divided into the soldering region 19 and the non-soldering region 18. That is, the surface of each pin 16 includes a region having a rough surface 27 and a region without having the rough surface 27. In this way, on one hand, by bonding the rough surface 27 with the plastic packaging material, the plastic packaging material and the rough surface 27 form a locking structure; and on the other hand, providing the pad 17 on the rough surface 27 improves the soldering effect, and avoids voids.

Further, the non-soldering region 18 and the soldering region 19 on a pin 16 are placed close to and away from the cutting line of the lead frame, respectively. For example, as shown in FIG. 2, the six (6) pins 16 are arranged in a first row and a second row along the up-down direction. The first row is above the second row. The first row includes 3 pins 16. The second row includes 3 pins 16. On the three pins 16 in the first row, the non-soldering regions 18 are located above the soldering regions 19. Thus, on the three pins 16 in the first row, the non-soldering regions 18 are all close to the cutting line on the upper part of the lead frame. Further, on the three pins 16 in the second row, the non-soldering regions 18 are all located below the soldering regions 19.

As such, the non-soldering regions 18 on the three pins 16 in the second row are all close to the cutting line on the lower part of the lead frame. Thus, the soldering regions 19 on the three pins 16 in the first row are adjacent to and opposite to the soldering regions 19 on the three pins 16 in the second row, respectively, such that the 6 soldering regions 19 on the 6 pins 16 stay together on the lead frame unit 11, which facilitates flip-chip soldering of the chip 26.

Further, as shown in FIG. 3, in a lead frame unit 11 of the second embodiment, the lead frame unit 11 includes a base island 21 and multiple pins 16 provided around the base island 21. Those in the art would recognize that the base island 21 may be used for attaching a chip 26. Furthermore, soldering regions 19 may be provided on the base island 21 and/or the pins. That is, the soldering regions 19 may be provided on the base island 21. Alternatively, the soldering regions 19 may be provided on the pins 16. Alternatively, the soldering regions 19 may be provided on the base island 21 and the pins 16. For example, as shown in FIG. 3, the soldering regions 19 are provided on the pins 16. Furthermore, at least one wire-bonding soldering portion may be provided in a soldering region 19. The at least one wire-bonding soldering portion is electrically connected to the chip 26 through a bonding wire 25. Thus, when the soldering region 19 is on the base island 21, the chip 26 is electrically connected to the wire-bonding soldering portion on the base island 21 through the bonding wire 25. When the soldering region 19 is on a pin 16, the chip 26 is electrically connected to the wire-bonding soldering portion on the pin 16 through the bonding wire 25. When soldering regions 19 are provided on the base island 21 and the pin 16, the chip 26 is electrically connected to the wire-bonding soldering portions on the base island 21 and the pin 16 through bonding wires 25.

Further, the lead frame in the embodiments of the present application also includes an outer frame 13. The outer frame 13 is provided around the outer sides of a plurality of lead frame units 11. For example, as shown in FIG. 1, two lead frame units 11 are located inside the outer frame 13. Further, each lead frame unit 11 also includes a plurality of connecting ribs 15. The plurality of connecting ribs 15 correspond to the plurality of pins 16. The correspondence herein may be that the number of the plurality of connecting ribs 15 is equal to the number of the plurality of pins 16.

For example, as shown in FIG. 1, each lead frame unit 11 include 6 pins 16 and 6 connecting ribs 15. Each connecting rib 15 is used to connect the outer frame 13 to a corresponding pin 16. The pins 16 are thus connected to the outer frame 13 through the connecting ribs 15.

Further, embodiments of the present application also provide a package. The package includes: the lead frame as described above; a plastic package for packaging the lead frame, where the plastic package and the rough surfaces 27 form a locking structure. On one hand, the package can enhance the joining strength between the plastic packaging material and the lead frame surface, and on the other hand, the package can improve the soldering effect, avoid problems such as wire-bonding flying and insecure soldering caused by rough surface, and avoid problems such as voids and pseudo soldering during flip-chip soldering.

Further, embodiments of the present application provide a roughening method for lead frame. The roughening method comprising: ablating the upper surface of each lead frame unit 11 to form ablation slots 28, such that the upper surface of the lead frame unit 11 is divided into soldering regions 19 that do not include the ablation slots 28 and non-soldering regions 18 that include the ablation slots 28.

Further, in the prior art, regions that do not need to be roughened are usually covered with a chemical mask, and regions that need to be roughened are roughened with chemical potions. Such a roughening process requires addition of procedures including film drying, exposing, developing, and so on, which leads to cost increase of the lead frame, and is not conducive to the overall competitiveness of the products.

The roughening method for lead frame according to the embodiments of the present invention uses laser to roughen the surface of the lead frame units 11 in a region-selective manner, which can avoid addition of procedures including film drying, exposing, developing, and so on, making the roughing operation more convenient and flexible, and reducing the cost. Furthermore, the roughening method for lead frame according to the embodiments of the present invention does not require the use of chemical potions, thereby avoiding causing secondary pollution to the lead frame. Moreover, by controlling laser energy, the roughening depth is controllable, the roughening depth may be made deeper than that made according to the conventional roughening method, and it is easier to lock the plastic packaging material.

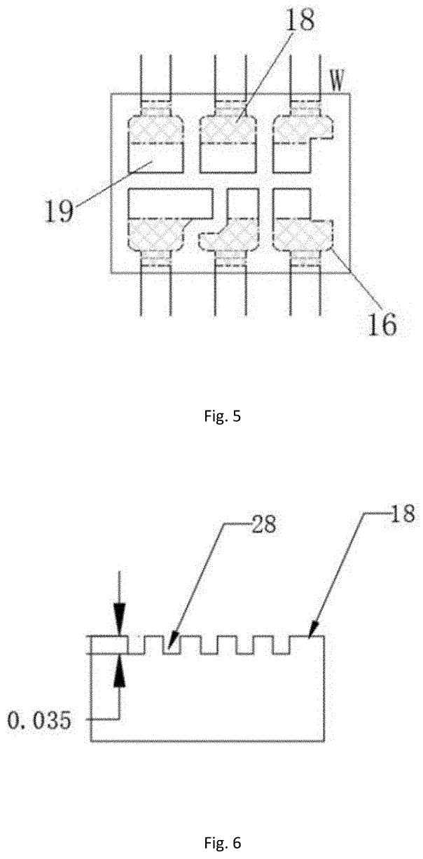

Specifically, as shown in FIG. 4, a lead frame body is first made in a corresponding shape according to the actual need. The lead frame body includes bodies of a plurality of lead frame units 11. As shown in FIG. 5, a portion of the upper surface of the body of each lead frame unit 11 is ablated by use of laser, to form ablation slots 28. Thus, the upper surface of the lead frame unit 11 is divided into soldering regions 19 that do not include the ablation slots 28 and non-soldering regions 18 that include the ablation slots 28. Furthermore, the power of the laser emitter is from 290 to 300 watts, and the laser emitter is used to emit continuous high speed laser pulses from 530 nm to 535 nm.

In one embodiment, after the soldering regions 19 that do not include the ablation slots 28 and the non-soldering regions 18 that include the ablation slots 28 are formed on the lead frame unit 11, the chip 26 is flip-chip soldered onto pads 17 in the soldering regions 19.

In another embodiment, after the soldering regions 19 that do not include the ablation slots 28 and the non-soldering regions 18 that include the ablation slots 28 are formed on the lead frame unit 11, the chip 26 is soldered to the wire-bonding soldering portions in the soldering regions 19 via bonding wires 25.

In the foregoing embodiments, each embodiment is described with its respective emphatic aspects. For aspects that are not described in detail in a certain embodiment, reference may be made to relevant descriptions of other embodiments.

The package, lead frame and roughening method thereof provided by the embodiments of the present invention have been described in detail above. In the present disclosure, specific examples are used to illustrate the principle and implementation of embodiments of the present invention. The descriptions of the above embodiments are only used to help understand the technical solutions and core ideas of the present application; those of ordinary skill in the art should understand that they can still make modifications to the technical solutions described in the foregoing embodiments, or make equivalent substitutions for certain technical features; however, these modifications or substitutions do not make the substance of the corresponding technical solutions depart from the scope of the technical solutions of the embodiments of the present invention.

Although the description has been described in detail, it should be understood that various changes, substitutions and alterations can be made without departing from the spirit and scope of this disclosure as defined by the appended claims. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, may perform substantially the same function or achieve substantially the same result as the corresponding embodiments described herein. Accordingly, the appended claims are intended to include within their scope such processes, machines, manufacture, compositions of matter, means, methods, or steps.

What is claimed:

1. A lead frame comprising:
a plurality of lead frame units, an upper surface of each of the plurality of lead frame units including a soldering region and a non-soldering region outside of the soldering region, wherein the non-soldering region includes a rough surface, and the soldering surface includes no rough surface.

2. The lead frame of claim 1, wherein each of the plurality of lead frame units includes a base island and a plurality of pins arranged around the base island, and the soldering region is arranged on the base island and/or on the plurality of pins.

3. The lead frame of claim 2, wherein the soldering region is electrically connectable to a chip through a bonding wire.

4. The lead frame of claim 1, wherein each of the plurality of lead frame units includes a plurality of pins, and the soldering region and the non-soldering region are arranged on the plurality of pins, the non-soldering region of a corresponding lead frame unit being arranged closer to a cutting line of the corresponding lead frame unit than the soldering region of the corresponding lead frame unit.

5. The lead frame of claim 4, wherein the soldering region is provided with at least one soldering pad, to which a chip is attachable using flip-chip soldering.

6. The lead frame of claim 4, further comprising an outer frame arranged around the plurality of lead frame units, wherein each of the plurality of lead frame units further includes a plurality of connecting ribs, the plurality of connecting ribs correspond to the plurality of pins, and each of the plurality of connecting ribs is configured to connect the outer frame with a corresponding pin of the plurality of pins.

7. The lead frame of claim 1, wherein the rough surface is formed using ablation slots, and the ablation slots are generated using high-speed laser pulses.

8. The lead frame of claim 7, wherein the high-speed laser pulses are generated by a laser emitter that has power in a range from 290 watts to 300 watts, and a wavelength of the high-speed laser pulses is in a range from 530 nanometer (nm) to 535 nm.

9. The lead frame of claim 7, wherein a depth of the ablation slots is in a range from 0.035 mm (millimeter) to 0.05 mm.

10. A package comprising:
a lead frame comprising a plurality of lead frame units, an upper surface of each of the plurality of lead frame units including a soldering region and a non-soldering region outside of the soldering region, wherein the non-soldering region includes a rough surface, and the soldering surface includes no rough surface; and
a plastic package for packaging the lead frame, wherein the plastic package and the rough surface form a locking structure.

11. The package of claim 10, wherein each of the plurality of lead frame units includes a base island and a plurality of pins arranged around the base island, and the soldering region is arranged on the base island and/or on the plurality of pins.

12. The package of claim 11, wherein the soldering region is electrically connectable to a chip through a bonding wire.

13. The package of claim 10, wherein each of the plurality of lead frame units further includes a plurality of pins, and the soldering region and the non-soldering region are arranged on the plurality of pins, the non-soldering region of a corresponding lead frame unit being arranged closer to a cutting line of the corresponding lead frame unit than the soldering region of the corresponding lead frame unit.

14. The package of claim 13, wherein the soldering region is provided with at least one soldering pad, to which a chip is attachable using flip-chip soldering.

15. The package of claim 10, wherein the rough surface is formed using ablation slots, and the ablation slots are generated using high-speed laser pulses.

16. The package of claim 15, wherein the high-speed laser pulses are generated by a laser emitter that has power in a range from 290 watts to 300 watts, and a wavelength of the high-speed laser pulses is in a range from 530 nanometer (nm) to 535 nm.

17. The lead frame of claim 15, wherein a depth of the ablation slots is in a range from 0.035 mm (millimeter) to 0.05 mm.

18. A method comprising:
providing a lead frame, the lead frame comprising a plurality of lead frame units; and
ablating, using a laser emitter, a portion of an upper surface of each of the plurality of lead frame units to form ablation slots in the portion of the upper surface, to generate, on the upper surface, a non-soldering region comprising the ablation slots and a soldering region excluding the ablation slots.

19. The method of claim 18, further comprising:
packaging the lead frame after the ablating, to generate a package.

20. The method of claim 18, wherein the laser emitter has power in a range from 290 watts to 300 watts, and the laser emitter is configured to emit high-speed laser pulses having a wavelength in a range from 530 nanometer (nm) to 535 nm.
